(19) United States
(12) Patent Application Publication
(10) Pub. No.: US 2025/0244415 A1
(43) Pub. Date: Jul. 31, 2025

(54) VERTICAL HALL ELEMENT

(71) Applicant: ABLIC Inc., Nagano (JP)

(72) Inventor: Shinji INAYOSHI, Nagano (JP)

(73) Assignee: ABLIC Inc., Nagano (JP)

(21) Appl. No.: 19/006,266

(22) Filed: Dec. 31, 2024

(30) Foreign Application Priority Data
Jan. 30, 2024 (JP) 2024-011528

(51) Int. Cl. G01R 33/07

(52) U.S. Cl. CPC G01R 33/077

(57) ABSTRACT

A vertical Hall element includes: an N-type epitaxial layer formed on a surface of a P-type semiconductor substrate; a first electrode group disposed on a surface of the N-type epitaxial layer and formed of three or more electrodes; and a P-type high-resistance diffusion layer disposed in a ring shape on an outer periphery separated from the first electrode group and including a second electrode group capable of being applied with a voltage such that an electric field with respect to the first electrode group becomes constant.

### CROSS-REFERENCE TO RELATED APPLICATION

This application claims the priority benefit of Japan application serial no. 2024-011528, filed on Jan. 30, 2024. The entirety of the above-mentioned patent application is hereby incorporated by reference herein and made a part of this specification.

### BACKGROUND

### Technical Field

The present invention relates to a vertical Hall element.

### Related Art

A Hall element may be easily formed on a surface of a semiconductor substrate and is capable of performing position detection and angle detection in a non-contact manner as a magnetic sensor, so the hall element is used in various applications.

Among Hall elements, a horizontal Hall element is generally well-known to detect a magnetic field component perpendicular to a surface of a semiconductor substrate, but various proposals have also been made for a vertical Hall element which detects a magnetic field component parallel to the surface of the semiconductor substrate.

For example, in a Hall element proposed, fuses are provided in multiple contact regions which flow a drive current to a magnetic detection part, and in the case where an imbalance occurs in a potential distribution inside the element due to stress or the like and an offset voltage is generated, the potential distribution inside the element can be adjusted.

### SUMMARY

A vertical Hall element according to an embodiment of the present invention is a vertical Hall element formed on a surface of a semiconductor substrate of a first conductivity type. The vertical Hall element includes an impurity diffusion layer of a second conductivity type, a first electrode group, and a high-resistance diffusion layer of the first conductivity type. The impurity diffusion layer is formed on the surface of the semiconductor substrate. The first electrode group is disposed on a surface of the impurity diffusion layer and is formed of three or more electrodes. The high-resistance diffusion layer is disposed in a ring shape on an outer periphery separated from the first electrode group and includes a second electrode group capable of being applied with a voltage such that an electric field with respect to the first electrode group becomes constant.

According to an aspect of the present invention, a vertical Hall element capable of removing an offset voltage with high accuracy can be provided.

### BRIEF DESCRIPTION OF THE DRAWINGS

FIG. 1 is a schematic plan view illustrating a vertical Hall element in an example of an embodiment of the present invention.

FIG. 2A is a schematic cross-sectional view taken along a line II-II in FIG. 1.

FIG. 2B is a view illustrating resistances between each electrode in a first electrode group and a second electrode group of this embodiment.

FIG. 3A is a schematic plan view illustrating a depletion layer and current paths generated in Phase 1 of a spinning current method in the vertical Hall element of this embodiment.

FIG. 3B is a circuit diagram illustrating connections with voltage sources and the electrodes in Phase 1 of the spinning current method in the vertical Hall element of this embodiment.

FIG. 4 is a schematic cross-sectional view illustrating the depletion layer and the current paths generated in Phase 1 of the spinning current method in the vertical Hall element of this embodiment.

FIG. 5A is a schematic plan view illustrating the depletion layer and the current paths generated in Phase 2 of the spinning current method in the vertical Hall element of this embodiment.

FIG. 5B is a circuit diagram illustrating the connections with the voltage sources and the electrodes in Phase 2 of the spinning current method in the vertical Hall element of this embodiment.

FIG. 6 is a schematic cross-sectional view illustrating the depletion layer and the current paths generated in Phase 2 of the spinning current method in the vertical Hall element of this embodiment.

FIG. 7A is a schematic plan view illustrating the depletion layer and the current paths generated in Phase 3 of the spinning current method in the vertical Hall element of this embodiment.

FIG. 7B is a circuit diagram illustrating the connections with the voltage sources and the electrodes in Phase 3 of the spinning current method in the vertical Hall element of this embodiment.

FIG. 8 is a schematic cross-sectional view illustrating the depletion layer and the current paths generated in Phase 3 of the spinning current method in the vertical Hall element of this embodiment.

FIG. 9A is a schematic plan view illustrating the depletion layer and the current paths generated in Phase 4 of the spinning current method in the vertical Hall element of this embodiment.

FIG. 9B is a circuit diagram illustrating the connections with the voltage sources and the electrodes in Phase 4 of the spinning current method in the vertical Hall element of this embodiment.

FIG. 10 is a schematic cross-sectional view illustrating the depletion layer and the current paths generated in Phase 4 of the spinning current method in the vertical Hall element of this embodiment.

FIG. 11 is a schematic plan view illustrating a conventional vertical Hall element.

FIG. 12A is a schematic cross-sectional view along a line XII-XII in FIG. 11.

FIG. 12B is a view illustrating resistances between each electrode in a conventional first electrode group.

FIG. 13A is a schematic plan view illustrating a depletion layer and current paths generated in Phase 1 of the spinning current method in the conventional vertical Hall element.

FIG. 13B is a circuit diagram illustrating connections with a voltage source and the electrodes in Phase 1 of the spinning current method in the conventional vertical Hall element.

FIG. 14 is a schematic cross-sectional view illustrating the depletion layer and the current paths generated in Phase 1 of the spinning current method in the conventional vertical Hall element.

FIG. 15A is a schematic plan view illustrating the depletion layer and the current paths generated in Phase 2 of the spinning current method in the conventional vertical Hall element.

FIG. 15B is a circuit diagram illustrating the connections with the voltage source and the electrodes in Phase 2 of the spinning current method in the conventional vertical Hall element.

FIG. 16 is a schematic cross-sectional view illustrating the depletion layer and the current paths generated in Phase 2 of the spinning current method in the conventional vertical Hall element.

FIG. 17A is a schematic plan view illustrating the depletion layer and the current paths generated in Phase 3 of the spinning current method in the conventional vertical Hall element.

FIG. 17B is a circuit diagram illustrating the connections with the voltage source and the electrodes in Phase 3 of the spinning current method in the conventional vertical Hall element.

FIG. 18 is a schematic cross-sectional view illustrating the depletion layer and the current paths generated in Phase 3 of the spinning current method in the conventional vertical Hall element.

FIG. 19A is a schematic plan view illustrating the depletion layer and the current paths generated in Phase 4 of the spinning current method in the conventional vertical Hall element.

FIG. 19B is a circuit diagram illustrating the connections with the voltage source and the electrodes in Phase 4 of the spinning current method in the conventional vertical Hall element.

FIG. 20 is a schematic cross-sectional view illustrating the depletion layer and the current paths generated in Phase 4 of the spinning current method in the conventional vertical Hall element.

### DESCRIPTION OF THE EMBODIMENTS

An aspect of the present invention provides a vertical Hall element capable of removing an offset voltage with high accuracy.

The present invention is based on a finding that in a vertical Hall element, an offset voltage is more likely to occur than in a horizontal Hall element, and it is difficult to remove the offset voltage with high accuracy even using a generally well-known spinning current method.

Specifically, in a vertical Hall element, the structure in a vertical direction of a semiconductor substrate is important, but it may be difficult to form a structure with high geometric symmetry in a semiconductor process, and an offset voltage is more likely to occur than in a horizontal Hall element. The spinning current method is known as a method of removing an offset voltage, and by calculating a correction value from output voltages upon changing a flow of current between each electrode in four phases, it is possible to remove the offset voltage caused by structural asymmetry due to manufacturing variations and the like.

However, upon changing the flow of current in each phase in the spinning current method, a distribution of a depletion layer width on a surface of an impurity diffusion layer, which serves as a current path, differs and a resistance value between electrodes changes, which may result in a decrease in removal accuracy of the offset voltage.

Thus, a vertical Hall element in this embodiment is configured to be capable of removing an offset voltage with high accuracy by separately disposing electrodes capable of applying voltages such that a distribution of a depletion layer width becomes constant in each phase.

Hereinafter, embodiments for implementing the present invention will be described in detail with reference to the drawings.

In the drawings, same constituent parts will be labeled with same reference signs, and repeated descriptions thereof may be omitted. Further, in the drawings, an X direction, a Y direction, and a Z direction are orthogonal to each other. A direction including the X direction and a direction (−X direction) opposite to the X direction will be referred to as an “X-axis direction”, a direction including the Y direction and a direction (−Y direction) opposite to the Y direction will be referred to as a “Y-axis direction”, and a direction including the Z direction and a direction (−Z direction, depth direction) opposite to the Z direction will be referred to as a “Z-axis direction” (height direction, thickness direction). In this regard, in the following embodiments, a surface on a Z direction side of each film may be referred to as a “surface”.

The drawings are schematic, and ratios of widths, lengths, and depths are not necessarily as illustrated in the drawings.

In the following, a first conductivity type will be described as a P-type and a second conductivity type will be described as an N-type.

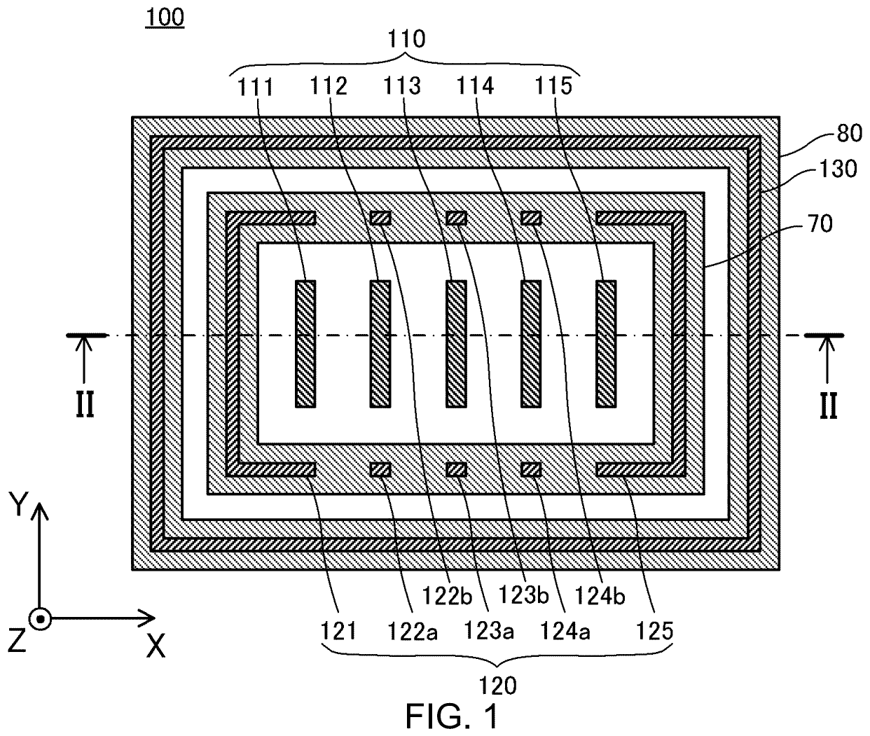

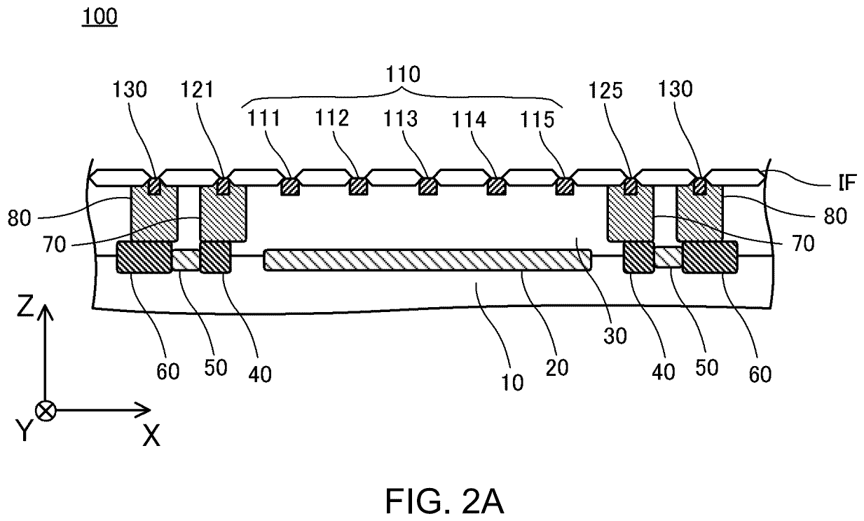

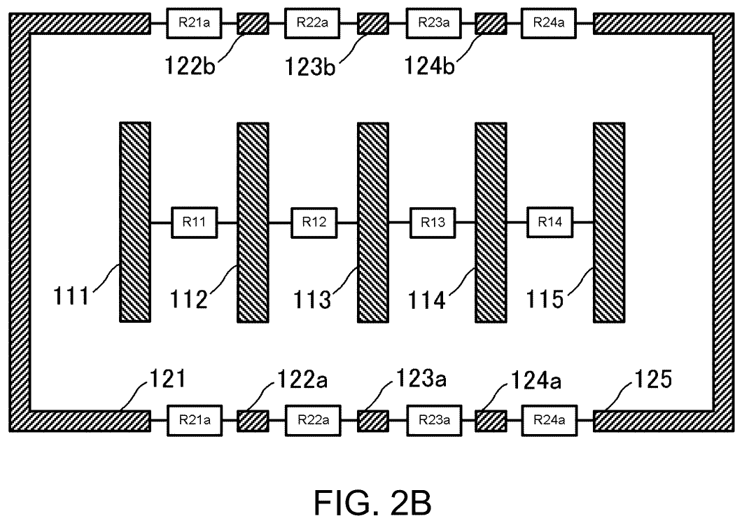

FIG. 1 is a schematic plan view illustrating a vertical Hall element in an example of the embodiment of the present invention. FIG. 2A is a schematic cross-sectional view taken along a line II-II in FIG. 1. FIG. 2B is view illustrating resistances between each electrode in a first electrode group and a second electrode group in this embodiment.

As illustrated in FIG. 1, a vertical Hall element 100 of this embodiment includes a first electrode group 110, and a P-type high-resistance diffusion layer 70 with a second electrode group 120 provided on an outer periphery of the first electrode group 110. Furthermore, the vertical Hall element 100 includes a P-type element isolation diffusion layer 80 disposed in a ring shape on an outer periphery of the P-type high-resistance diffusion layer 70.

Further, as illustrated in FIG. 2A, the vertical Hall element 100 is formed on a surface of a P-type semiconductor substrate 10, and includes N-type buried layers 20 and 50, an N-type epitaxial layer 30 as an impurity diffusion layer, and P-type buried layers 40 and 60.

The first electrode group 110 is an electrode group for the vertical Hall element 100 to function as a magnetic sensor, and is also used in performing a correction to remove an offset voltage according to the spinning current method. The first electrode group 110 is formed of five electrodes 111 to 115.

The electrodes 111 to 115 are disposed on a straight line on a surface of the N-type epitaxial layer 30, and are each formed of an N-type impurity region with a concentration higher than the N-type epitaxial layer 30. The electrodes 111 to 115 all have a same structure, are rectangular as viewed in a plan view, and are arranged at equal intervals in a short side direction thereof. Accordingly, since the electrodes 111 to 115 exhibit high structural symmetry, the offset voltage outputted can be reduced even in the case where an external magnetic field is not applied.

Further, the electrodes 111 to 115 are respectively connected to voltage sources by wirings (not illustrated), and are applied with required voltages.

With the vertical Hall element 100 functioning as a magnetic sensor, the electrodes 111, 113, and 115 become drive current supply electrodes, and the electrodes 112 and 114 become Hall voltage output electrodes. In performing the correction to remove the offset voltage according to the spinning current method, the drive current supply electrodes and the Hall voltage output electrodes may be replaced to acquire required output voltages Vout1 to Vout4.

The second electrode group 120 is formed on a surface of the P-type high-resistance diffusion layer 70, and is applied with a voltage such that a width of a depletion layer generated between the first electrode group 110 and the P-type high-resistance diffusion layer 70 becomes constant in each phase of the spinning current method. The second electrode group 120 is formed of eight electrodes 121, 122a, 122b, 123a, 123b, 124a, 124b, and 125.

The electrodes 121, 122a, 122b, 123a, 123b, 124a, 124b, and 125 are each formed of a P-type impurity region with a concentration higher than the P-type high-resistance diffusion layer 70. The eight electrodes are disposed at positions at which an electric field between the P-type high-resistance diffusion layer 70 and the first electrode group 110 can be easily configured to be constant. In this embodiment, the electrode 121 corresponds to the electrode 111, the electrodes 122a and 122b correspond to the electrode 112, the electrodes 123a and 123b correspond to the electrode 113, the electrodes 124a and 124b correspond to the electrode 114, and the electrode 125 corresponds to the electrode 115. Further, the electrodes 121 and 125 are disposed to cover one lateral surface of each of the electrodes 111 and 115. The electrodes 122a, 122b, 123a, 123b, 124a, and 124b are disposed on extensions of both ends in long side directions of the electrodes 112 to 114, and are rectangles with two opposing sides having a width of the electrodes 112 to 114 in a plan view.

The eight electrodes are respectively connected to voltage sources by wirings (not illustrated), and are applied with voltages to configure a potential difference to be constant between each electrode.

On a surface of the P-type element isolation diffusion layer 80, an electrode 130 is formed of a P-type impurity region with a concentration higher than the P-type element isolation diffusion layer 80. The electrode 130 is grounded by a wiring (not illustrated), and sets a potential of the P-type element isolation diffusion layer 80 to 0 V.

The P-type semiconductor substrate 10 is a silicon wafer to which P-type impurities are added.

The N-type buried layer 20 is formed in a boundary vicinity between the P-type semiconductor substrate 10 and the N-type epitaxial layer 30, and is disposed below the first electrode group 110.

This embodiment focuses on the depletion layer which is generated in a current path flowing to a region near the surface of the N-type epitaxial layer 30, but a current path is also present to pass downward through the N-type epitaxial layer 30 and through the N-type buried layer 20, and then flow upward through the N-type epitaxial layer 30. In other words, the current flowing in an in-plane direction of the P-type semiconductor substrate 10 flows throughout the entirety of the N-type buried layer 20 and the N-type epitaxial layer 30. Thus, in acting as a magnetic sensor, the N-type buried layer 20 and the N-type epitaxial layer 30 become a current path for the drive current and function as a magnetic sensing part.

The N-type epitaxial layer 30 is provided on the P-type semiconductor substrate 10, and N-type impurities are injected and diffused therein.

In this embodiment, an impurity concentration of the N-type epitaxial layer 30 is constant, but the impurity concentration may also be increased as a depth increases. Accordingly, by configuring a concentration gradient of impurities such that a resistance value of a deepest current path becomes similar to a resistance value of a current path passing through a shallow spot, the current path can be expanded with good balance, and magnetic sensitivity of the vertical Hall element 100 can be enhanced.

The P-type buried layer 40 is formed in a boundary vicinity between the P-type semiconductor substrate 10 and the N-type epitaxial layer 30. The P-type buried layer 40 is disposed at a position separated from the N-type buried layer 20 to contact a bottom surface of the P-type high-resistance diffusion layer 70.

Similar to the N-type buried layer 20, the N-type buried layer 50 is formed in a boundary vicinity between the P-type semiconductor substrate 10 and the N-type epitaxial layer 30. The N-type buried layer 50 is disposed to contact the P-type buried layer 40 by a lateral surface, and contact the bottom surface of the P-type high-resistance diffusion layer 70.

Similar to the P-type buried layer 40, the P-type buried layer 60 is formed in a boundary vicinity between the P-type semiconductor substrate 10 and the N-type epitaxial layer 30. The P-type buried layer 60 is disposed to contact the N-type buried layer 50 by a lateral surface, and contact a bottom surface of the P-type element isolation diffusion layer 80.

The P-type high-resistance diffusion layer 70 is disposed in a rectangular ring shape on an outer periphery separated from the first electrode group 110. Since the P-type high-resistance diffusion layer 70 exhibits a high resistance, the current at the time of applying a voltage to each electrode of the second electrode group 120 can be reduced. Since the shape of the P-type high-resistance diffusion layer 70 is a ring shape, the current from the first electrode group 110 can be prevented from diffusing, and magnetic sensitivity and accuracy of removing the offset voltage can be enhanced.

An inner peripheral part of the P-type high-resistance diffusion layer 70 may be located at a constant distance from an outer peripheral part of the first electrode group 110. Accordingly, the electric field between the P-type high-resistance diffusion layer 70 and the first electrode group 110 can be easily configured to be constant.

The outer peripheral part of the first electrode group 110 refers to a minimum enclosing line capable of enclosing all the five electrodes 111 to 115.

The P-type element isolation diffusion layer 80 is disposed in a ring shape on an outer periphery separated from the P-type high-resistance diffusion layer 70. The P-type element isolation diffusion layer 80 is formed deeply to contact the P-type buried layer 60. Accordingly, the vertical Hall element 100 is electrically isolated from other regions (not illustrated) on the P-type semiconductor substrate 10 surrounding the vertical Hall element 100.

In a region on the P-type semiconductor substrate 10 which is electrically isolated from the vertical Hall element 100, elements such as transistors are provided to form at least one of a circuit for processing output signals from the vertical Hall element 100 and a circuit for supplying signals to the vertical Hall element 100.

An insulating film IF is a silicon oxide film formed on the surface of the N-type epitaxial layer 30 according to a local oxidation of silicon (LOCOS) method. The insulating film IF is provided around the first electrode group 110 and the second electrode group 120.

For example, the insulating film IF does not have a conductivity type, from a viewpoint that a depletion layer is generated near the surface in the case of being an insulating film having a conductivity type such as a P-type electrode isolation diffusion layer.

Furthermore, as illustrated in FIG. 2B, resistors R11 to R14 represent electrical resistances in the current paths between each electrode 111 to 115 in the first electrode group 110. The resistors R11 to R14 have substantially equal resistance values since each electrode 111 to 115 is arranged at equal intervals.

Resistors R21a to R24b represent electrical resistances in the current paths between adjacent electrodes of the second electrode group 120. The resistors R21a to R24b have substantially equal resistance values since the intervals between adjacent electrodes in the second electrode group 120 are the same.

In this manner, with the resistance values between each electrode being substantially equal in each electrode group, the voltage applied from the voltage source can be easily divided to ½.

Next, a method of manufacturing the vertical Hall element of this embodiment will be described.

First, P-type impurities or N-type impurities are selectively injected into regions where each buried layer is to be formed in the P-type semiconductor substrate 10, and then an N-type epitaxial layer 30 containing N-type impurities is formed thereon. By selectively injecting and diffusing P-type impurities on the surface of the N-type epitaxial layer 30, a P-type high-resistance diffusion layer 70 and a P-type element isolation diffusion layer 80 are formed. Then, taking, as a mask, an insulating film IF formed according to the LOCOS method on the surface of the N-type epitaxial layer 30, N-type impurities are injected from the surface of the N-type epitaxial layer 30 to a high concentration to form a first electrode group 110. Further, taking the insulating film IF as a mask, P-type impurities are injected from the surfaces of the P-type high-resistance diffusion layer 70 and the P-type element isolation diffusion layer 80 to a high concentration to form a second electrode group 120 and an electrode 130.

In this manner, the vertical Hall element 100 can be formed.

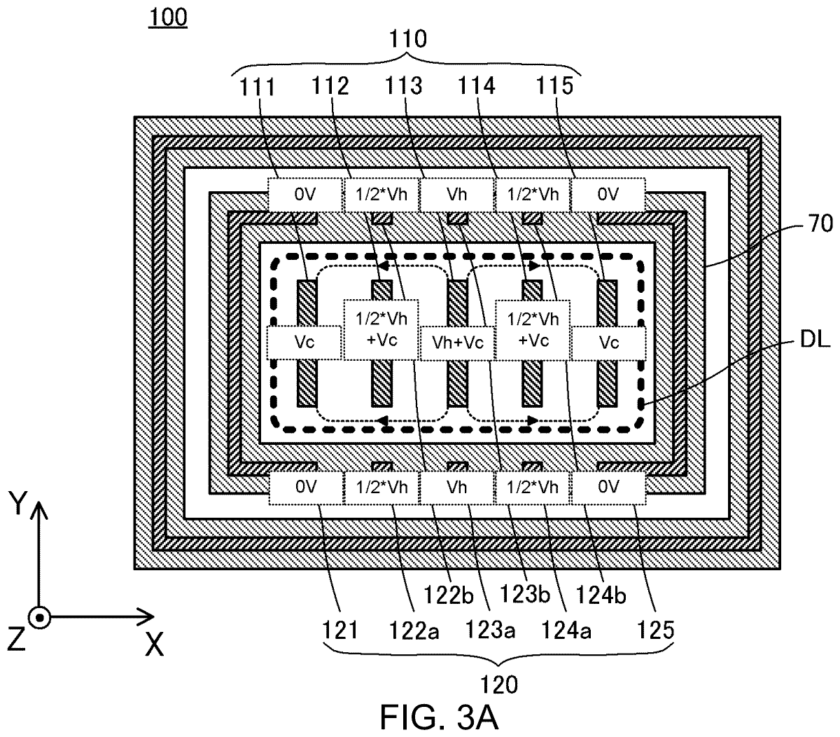

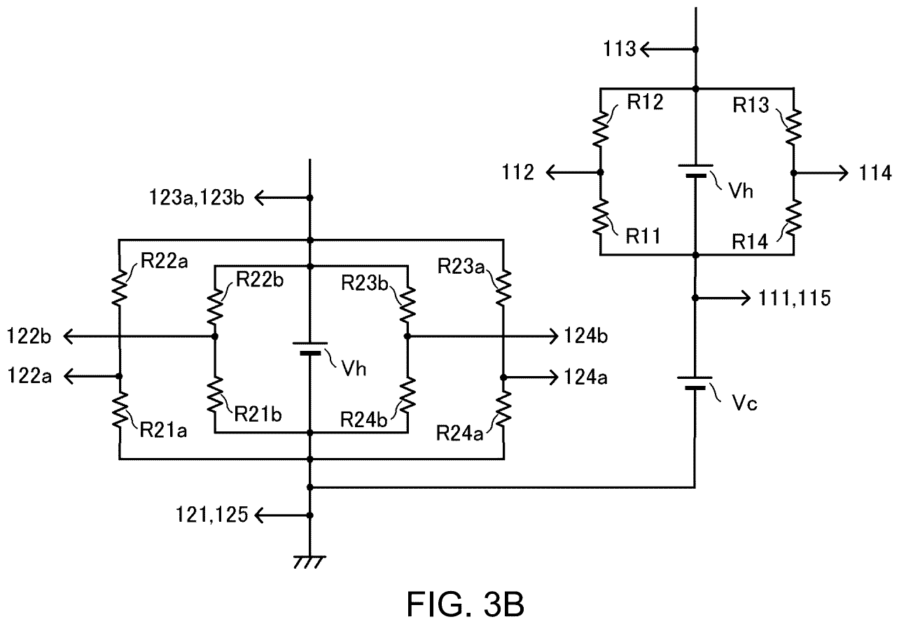

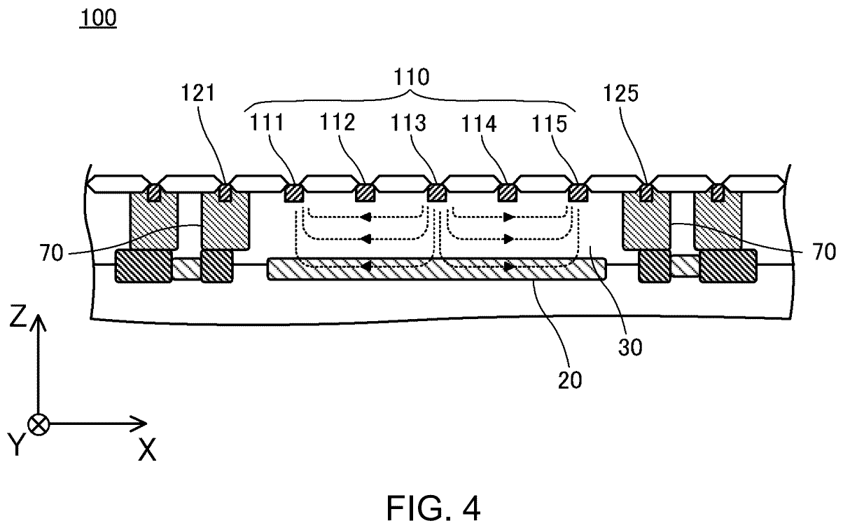

Next, a principle of detecting a −Y direction component of an external magnetic field in the vertical Hall element 100 will be described with reference to FIG. 3A, FIG. 3B, and FIG. 4.

For the vertical Hall element 100 to detect a magnetic field, a drive current is flowed respectively in the +X direction and the −X direction from the electrode 113 at a center toward the electrodes 111 and 115 at both ends. Upon application of an external magnetic field in the −Y direction to this drive current, Lorentz forces are generated respectively in the +Z direction with respect to charged particles of the drive current in the +X direction and in the −Z direction with respect to charged particles of the drive current in the −X direction, thereby generating Hall voltages which are potential differences of reverse positivity/negativity. By outputting a voltage between the electrode 112 and the electrode 114 by adding absolute values of these potential differences, the vertical Hall element 100 can detect the external magnetic field applied from the −Y direction with good sensitivity.

The electrodes 114 and 115 are disposed to remove the offset voltage, and if an external magnetic field is to be detected simply, the three electrodes 111 to 113 are sufficient.

Next, a method of removing an offset voltage of the vertical Hall element 100 according to the spinning current method will be described with reference to FIG. 3A to FIG. 10.

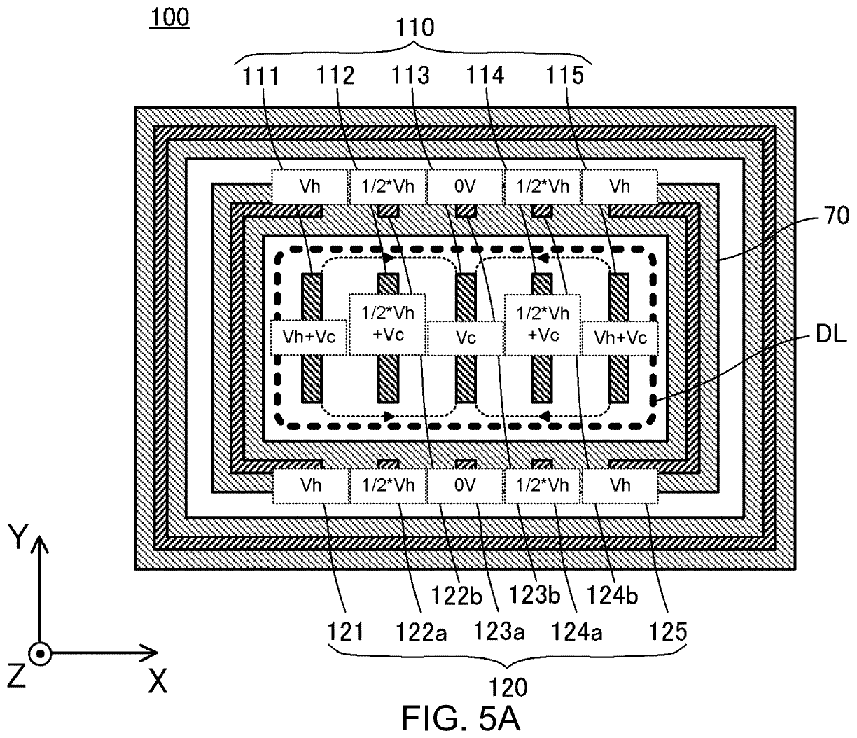

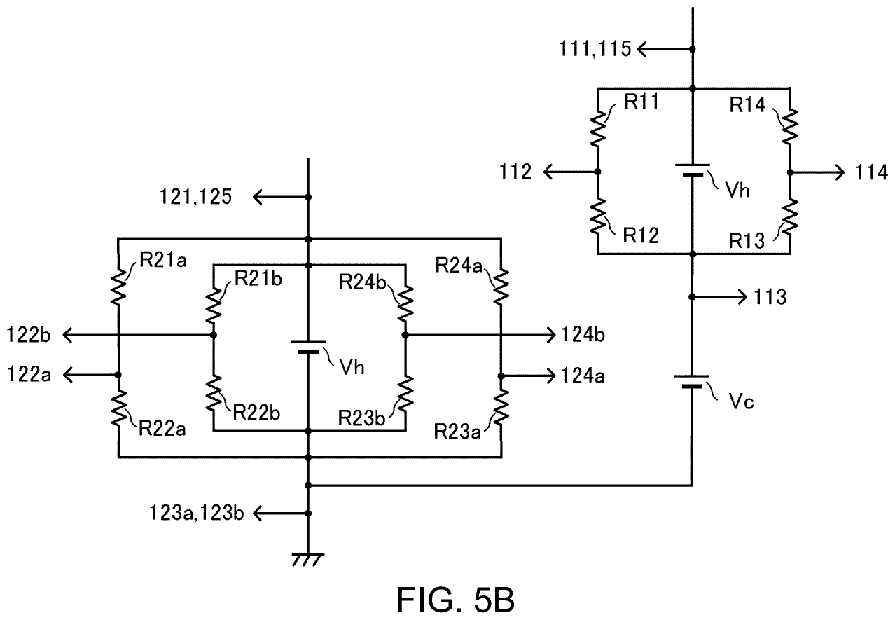

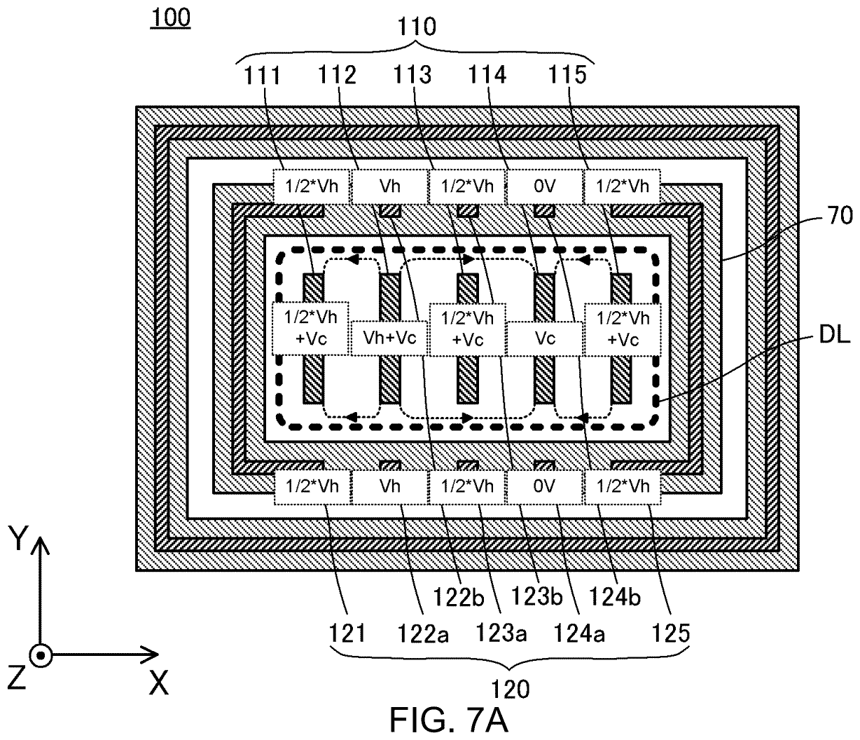

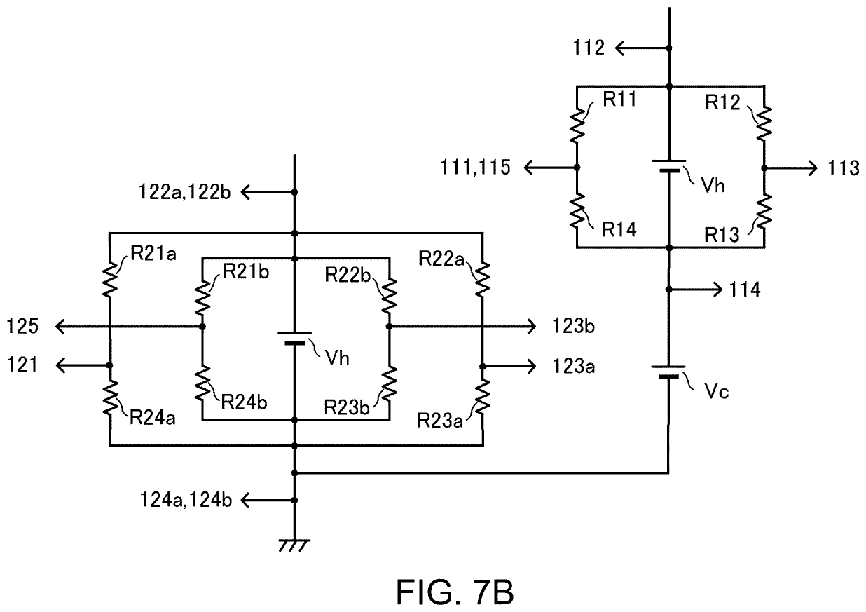

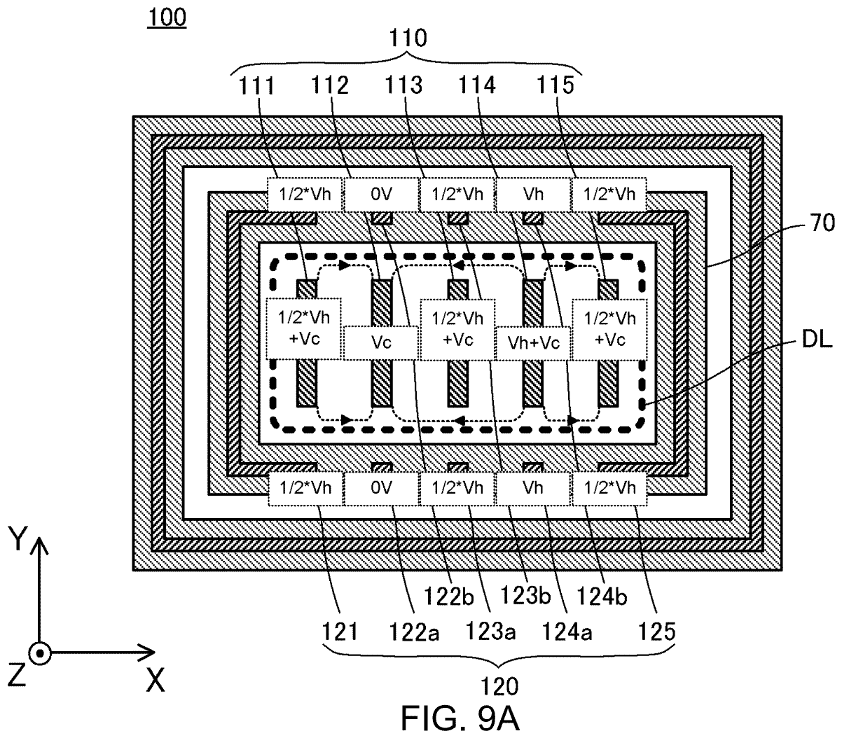

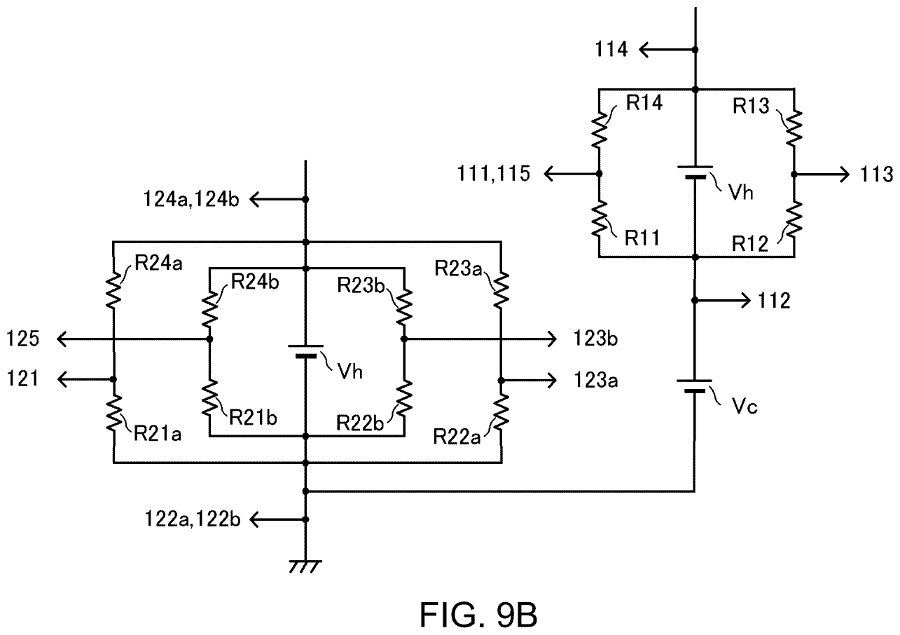

FIG. 3B, FIG. 5B, FIG. 7B, and FIG. 9B respectively illustrate voltage sources generating voltages Vh and Vc, and connections with each electrode of the first electrode group 110 and the second electrode group 120. Changes in the connections in each phase may be realized by performing switching using switching elements or the like.

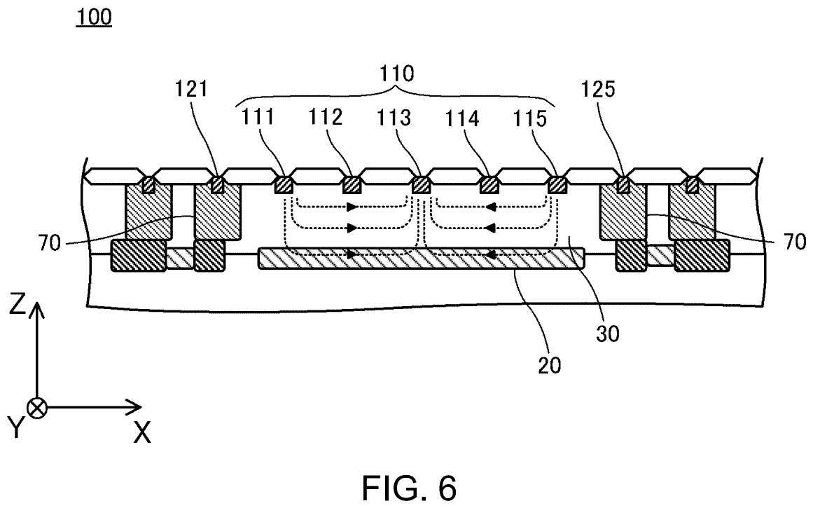

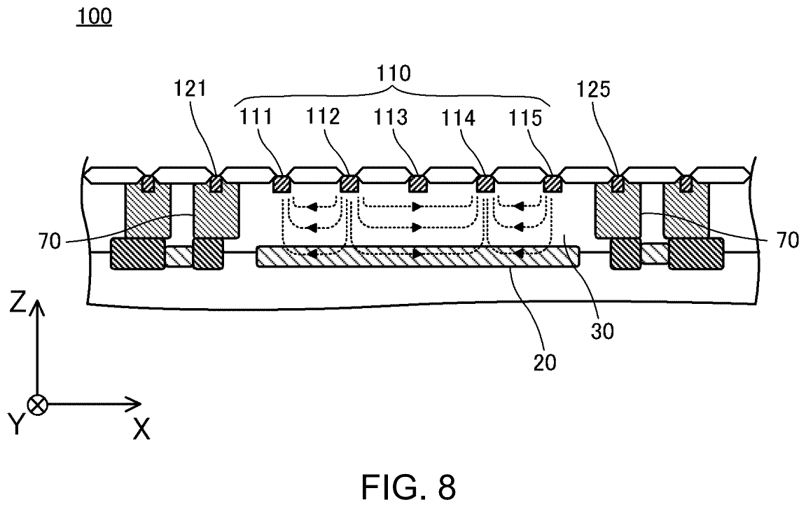

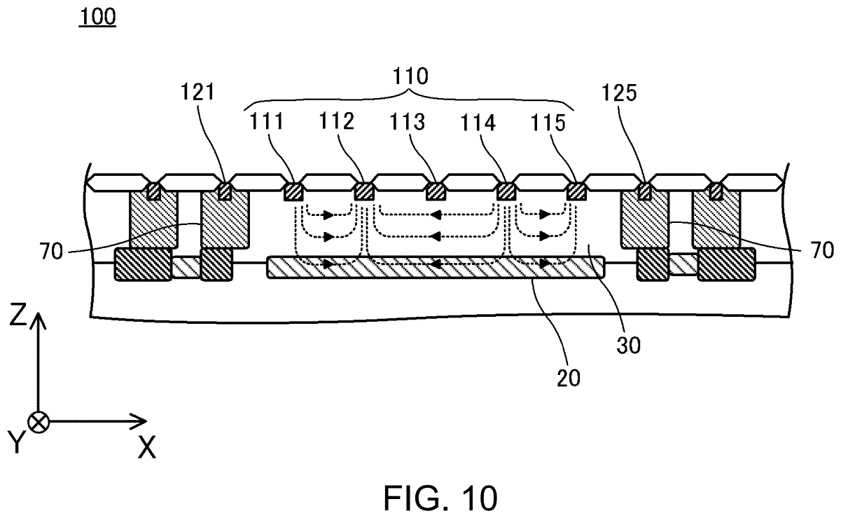

Further, in FIG. 4, FIG. 6, FIG. 8, and FIG. 10, a depletion layer is formed on an inner peripheral side of the P-type high-resistance diffusion layer 70, but illustration of this depletion layer is omitted.

### <Phase 1>

In Phase 1, as illustrated in FIG. 3A, FIG. 3B, and FIG. 4, taking the electrodes 111, 113, and 115 as current supply electrodes, a current is flowed from the electrode 113 respectively to the electrodes 111 and 115. Thus, a voltage of Vh+Vc is applied to the electrode 113, a voltage of Vc is applied to the electrodes 111 and 115, and a voltage of (½)×Vh+Vc is applied to the electrodes 112 and 114. As a result, current paths are as indicated by dotted lines (thin lines) in the figure, and taking the electrodes 112 and 114 as voltage output electrodes, a voltage between the electrode 112 and the electrode 114 is obtained an output voltage Vout1.

At this time, voltages lower by a voltage of Vc than the voltages applied to the corresponding first electrode group 110 are applied respectively to the second electrode group 120, and the electric field generated in the N-type epitaxial layer 30 between the first electrode group 110 and the P-type high-resistance diffusion layer 70 is configured to be constant.

Specifically, a voltage of Vh is applied to the electrodes 123a and 123b corresponding to the electrode 113, to which a voltage of Vh+Vc is applied. With respect to the electrodes 111 and 115, to which a voltage of Vc is applied, the electrodes 121 and 125 are set to 0 V. A voltage of (½)×Vh is applied to the electrodes 122a, 122b, 124a, and 124b corresponding to the electrodes 112 and 114, to which a voltage of (½)×Vh+Vc is applied. Accordingly, the electric field generated in the N-type epitaxial layer 30 between the first electrode group 110 and the P-type high-resistance diffusion layer 70 is configured to be constant, and a width of a depletion layer DL indicated by a dotted line (thick line) in the figure can be configured to be constant.

Vc is a voltage higher than Vh.

### <Phase 2>

In Phase 2, as illustrated in FIG. 5A, FIG. 5B, and FIG. 6, with the direction of flowing a current reversed compared to FIG. 3A and FIG. 4, a current is flowed respectively from the electrodes 111 and 115 to the electrode 113. Thus, a voltage of Vh+Vc is applied to the electrodes 111 and 115, a voltage of Vc is applied to the electrode 113, and a voltage of (½)×Vh+Vc is applied to the electrodes 112 and 114. As a result, the current paths are as indicated by dotted lines (thin lines) in the figure, and similar to Phase 1, taking the electrodes 112 and 114 as voltage output electrodes, a voltage between the electrode 112 and the electrode 114 is obtained as an output voltage Vout2.

At this time, to configure the width of the depletion layer DL to be similar to Phase 1, voltages lower by a voltage of Vc than the voltages applied to the corresponding first electrode group 110 are respectively applied to the second electrode group 120.

Specifically, with respect to the electrodes 111 and 115, to which a voltage of Vh+Vc is applied, a voltage of Vh is applied to the electrodes 121 and 125. The electrodes 123a and 123b corresponding to the electrode 113, to which a voltage of Vc is applied, are set to 0 V. A voltage of (½)×Vh is applied to the electrodes 122a, 122b, 124a, and 124b corresponding to the electrodes 112 and 114, to which a voltage of (½)×Vh+Vc is applied.

### <Phase 3>

In Phase 3, as illustrated in FIG. 7A, FIG. 7B, and FIG. 8, the current supply electrodes and the voltage output electrodes are replaced compared to FIG. 3A to FIG. 6, a current is flowed from the electrode 112 respectively to the electrodes 111 and 114, and a current is flowed from the electrode 115 to the electrode 114. Thus, a voltage of Vh+Vc is applied to the electrode 112, a voltage of Vc is applied to the electrode 114, and a voltage of (½)×Vh+Vc is applied to the electrodes 111, 113, and 115. As a result, current paths are as indicated by dotted lines (thin lines) in the figure, and taking the electrodes 111, 113, and 115 as voltage output electrodes, a voltage between the electrode 113 and the electrode 111 or the electrode 115 is obtained as an output voltage Vout3.

At this time, to configure the width of the depletion layer DL to be similar to Phases 1 and 2, voltages lower by a voltage of Vc than the voltages applied to the corresponding first electrode group 110 are respectively applied to the second electrode group 120.

Specifically, with respect to the electrode 112, to which a voltage of Vh+Vc is applied, a voltage of Vh is applied to the electrodes 122a and 122b. The electrodes 124a and 124b corresponding to the electrode 114, to which a voltage of Vc is applied, are set to 0 V. A voltage of (½)×Vh is applied to the electrodes 121, 123a, 123b, and 125 corresponding to the electrodes 111, 113, and 115, to which a voltage of (½)×Vh+Vc is applied.

### <Phase 4>

In Phase 4, as illustrated in FIG. 9A, FIG. 9B, and FIG. 10, with the direction of flowing a current reversed compared to FIG. 7A and FIG. 8, a current is flowed from the electrode 114 respectively to electrodes 112 and 115, and a current is flowed from the electrode 111 to the electrode 112. Thus, a voltage of Vh+Vc is applied to the electrode 114, a voltage of Vc is applied to the electrode 112, and a voltage of (½)×Vh+Vc is applied to the electrodes 111, 113, and 115. As a result, current paths are as indicated by dotted lines (thin lines) in the figure, and similar to Phase 3, taking the electrodes 111, 113, and 115 as voltage output electrodes, a voltage between the electrode 113 and the electrodes 111 and 115 is obtained an output voltage Vout4.

At this time, to configure the width of the depletion layer DL to be similar to Phases 1 to 3, voltages lower by a voltage of Vc than the voltages applied to the corresponding first electrode group 110 are applied respectively to the second electrode group 120.

Specifically, with respect to the electrode 114, to which a voltage of Vh+Vc is applied, a voltage of Vh is applied to the electrodes 124a and 124b. The electrodes 122a and 122b corresponding to the electrode 112, to which a voltage of Vc is applied, are set to 0 V. A voltage of (½)×Vh is applied to the electrodes 121, 123a, 123b, and 125 corresponding to the electrodes 111, 113, and 115, to which a voltage of (½)×Vh+Vc is applied.

In this manner, even if the flow of current is changed in each phase of the spinning current method, the width of the depletion layer DL on the surface of the N-type epitaxial layer 30, which serves as the current path, remains constant. Thus, upon removing the offset voltage by calculating a correction value from the output voltages Vout1 to Vout4, the resistance values between electrodes become equal in each phase, and removal accuracy can be improved.

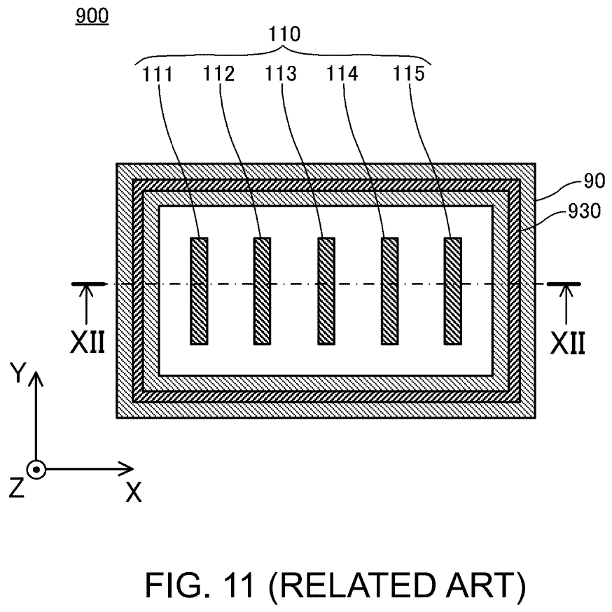

Next, to compare between a conventional vertical Hall element and the vertical Hall element of this embodiment, a method of removing an offset voltage of a conventional vertical Hall element according to the spinning current method will be described with reference to FIG. 11 to FIG. 20.

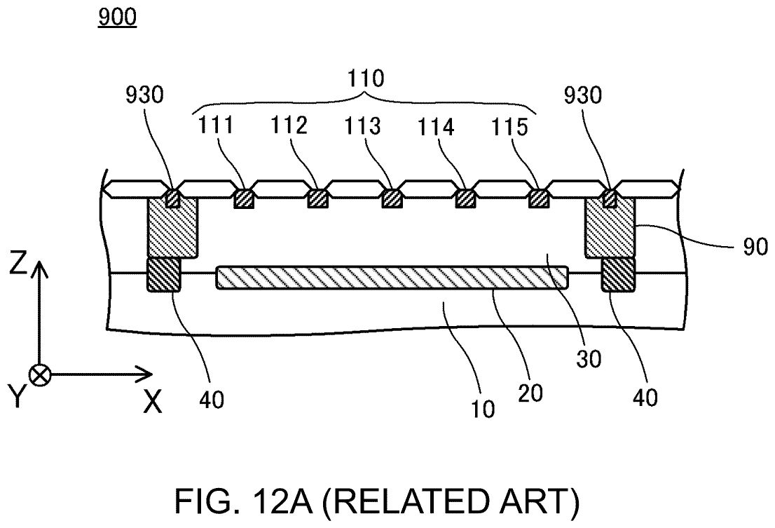

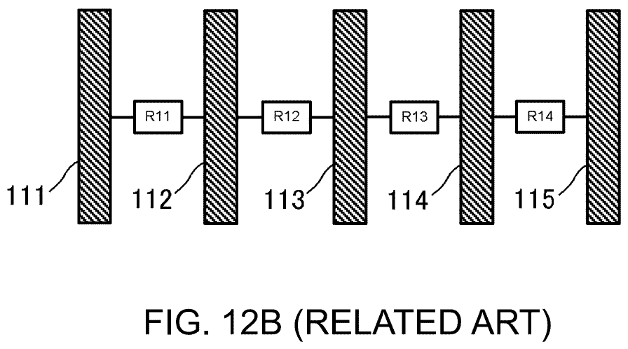

FIG. 11 is a schematic plan view illustrating a conventional vertical Hall element. FIG. 12A is a schematic cross-sectional view taken along a line XII-XII in FIG. 11. FIG. 12B is a view illustrating resistances between each electrode in a conventional first electrode group.

A conventional vertical Hall element 900 includes an electrode 930 and a P-type element isolation diffusion layer 90 disposed in place of the second electrode group 120 and the P-type high-resistance diffusion layer 70 in the vertical Hall element 100. In addition, the conventional vertical Hall element 900 is similar to the vertical Hall element 100, except for not including the electrode 130, the P-type buried layers 40 and 60, the N-type buried layer 50, and the P-type element isolation diffusion layer 80 present in the vertical Hall element 100.

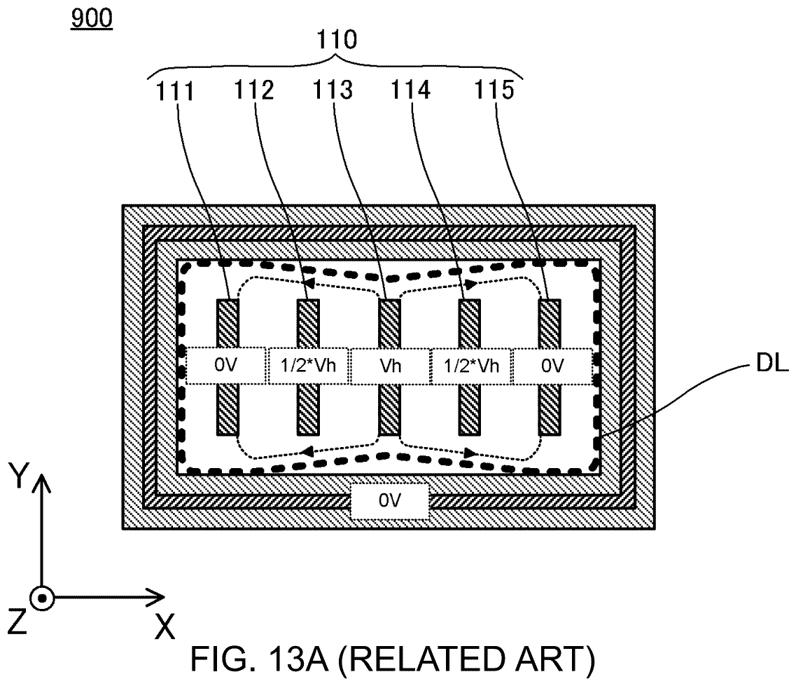

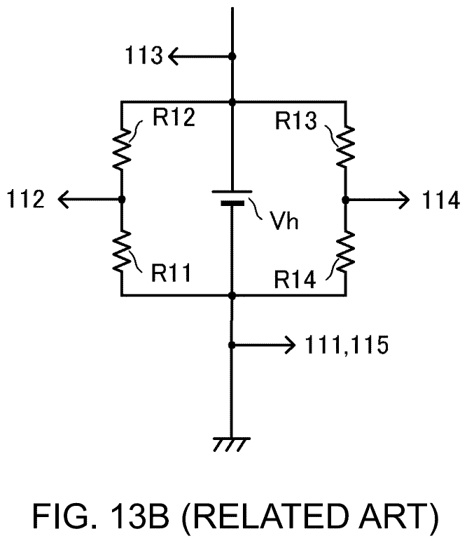

In the case of removing an offset voltage of the conventional vertical Hall element 900 according to the spinning current method, the width of the depletion layer DL on the surface of the N-type epitaxial layer 30 does not remain constant upon changing a flow of current in each phase, which will be described with reference to FIG. 13A to FIG. 20.

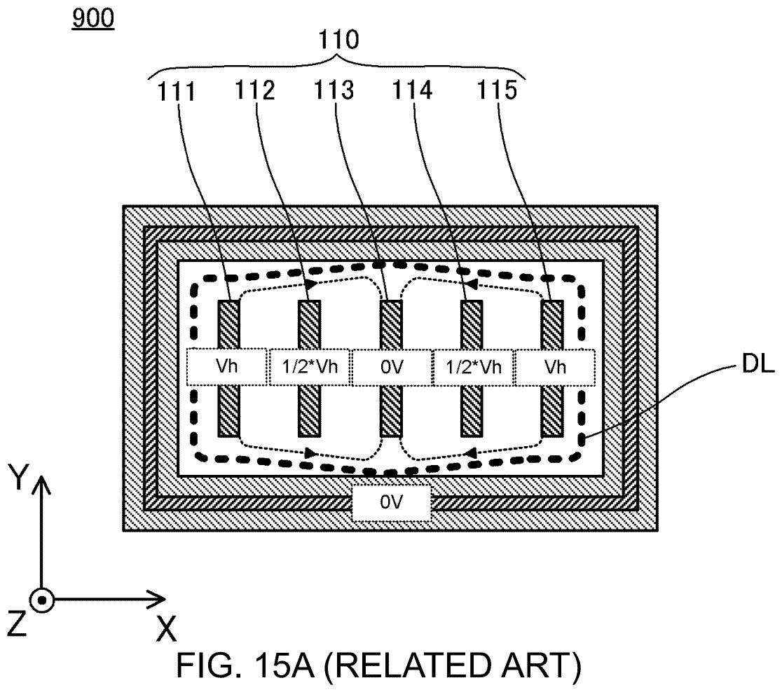

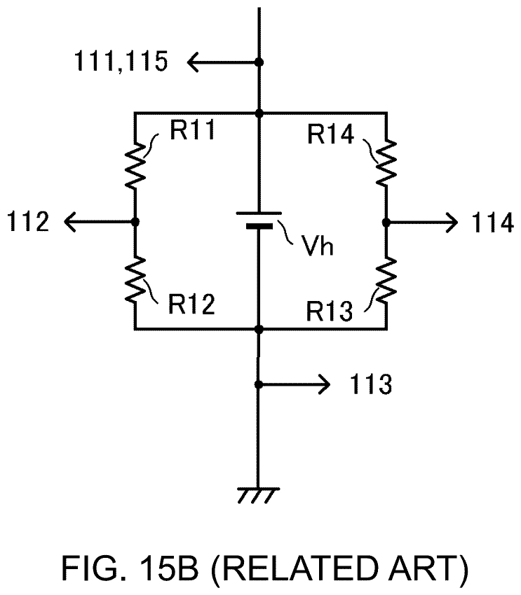

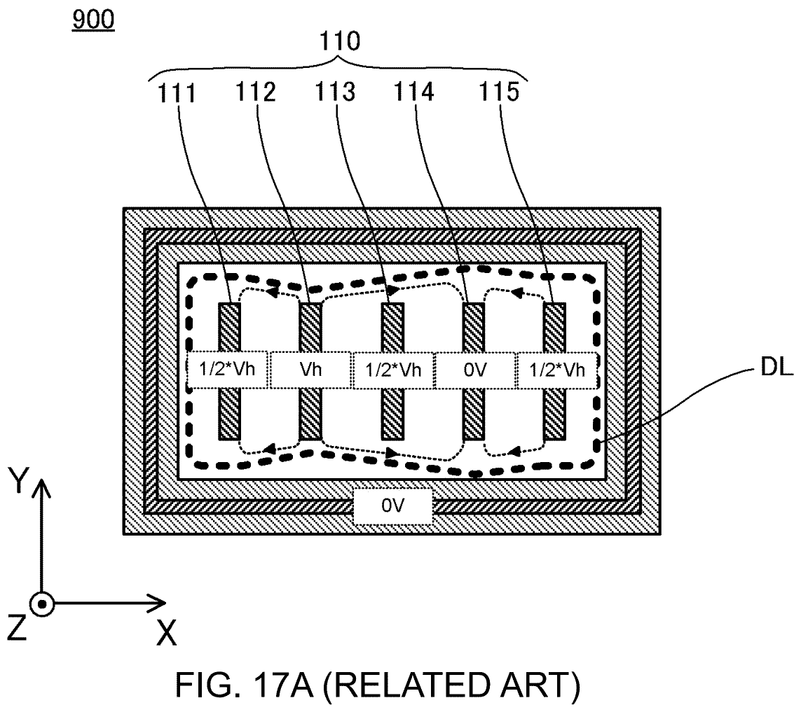

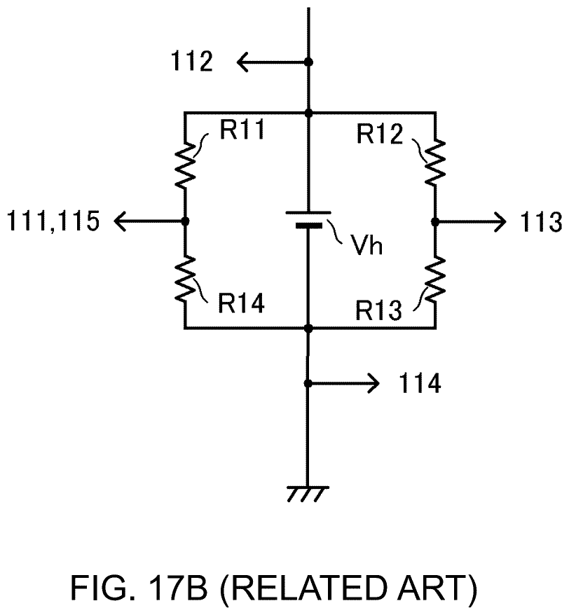

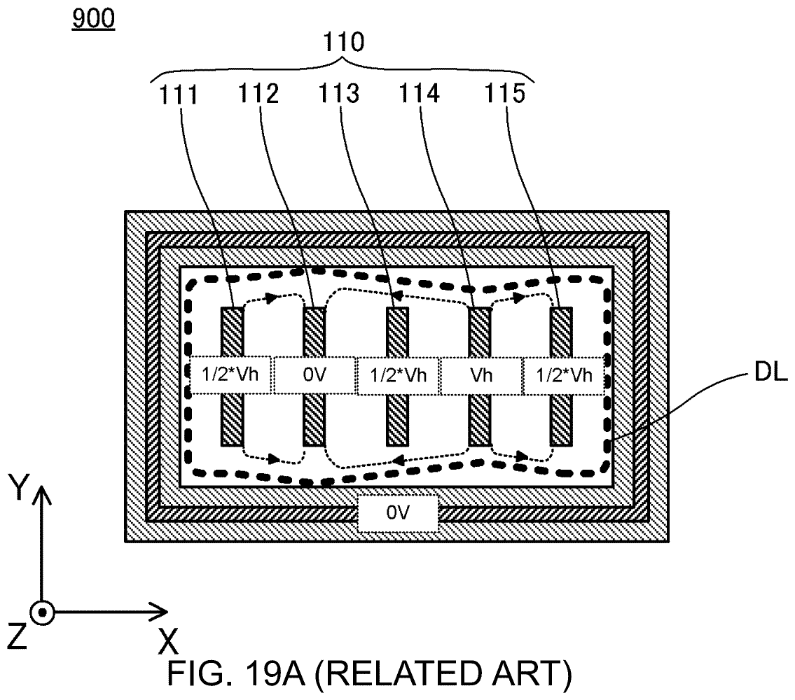

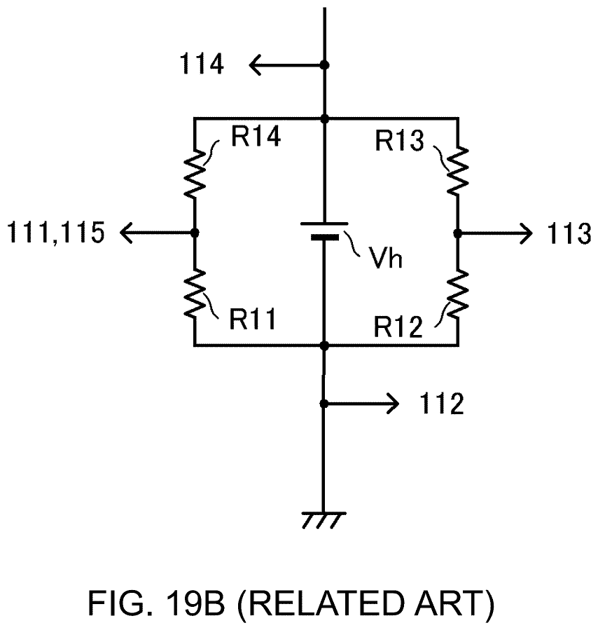

FIG. 13B, FIG. 15B, FIG. 17B, and FIG. 19B illustrate a voltage source generating of a voltage of Vh, and connections with each electrode of the first electrode group 110. Changes in the connections in each phase may be realized by performing switching using switching elements or the like.

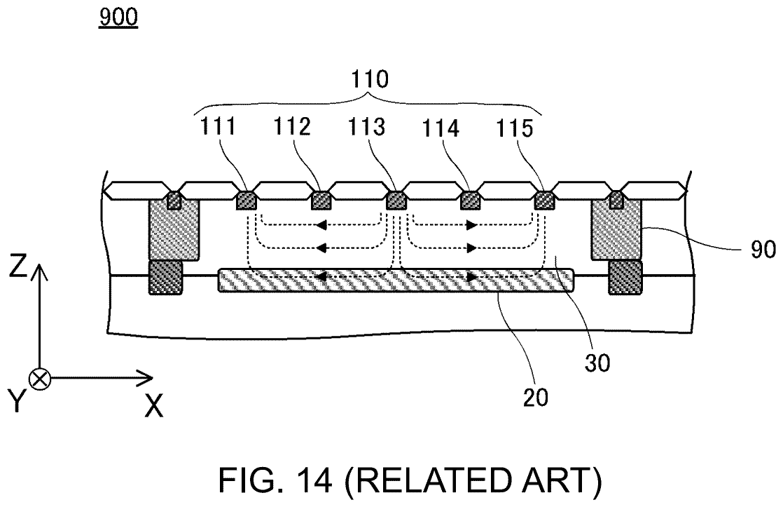

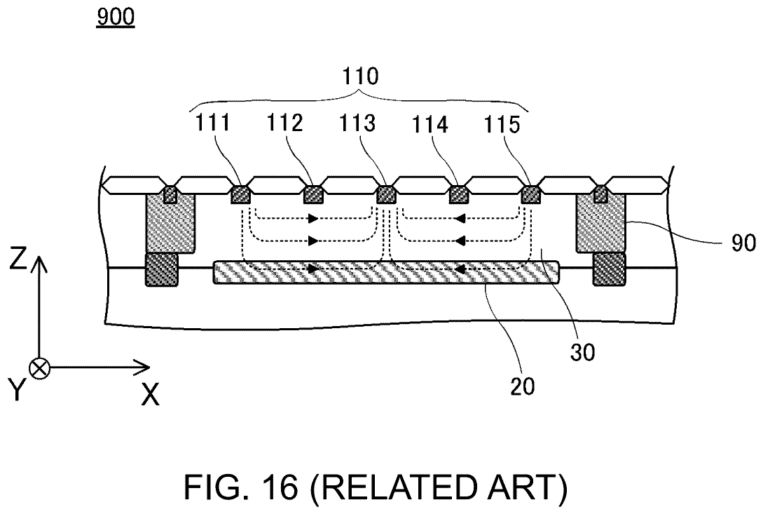

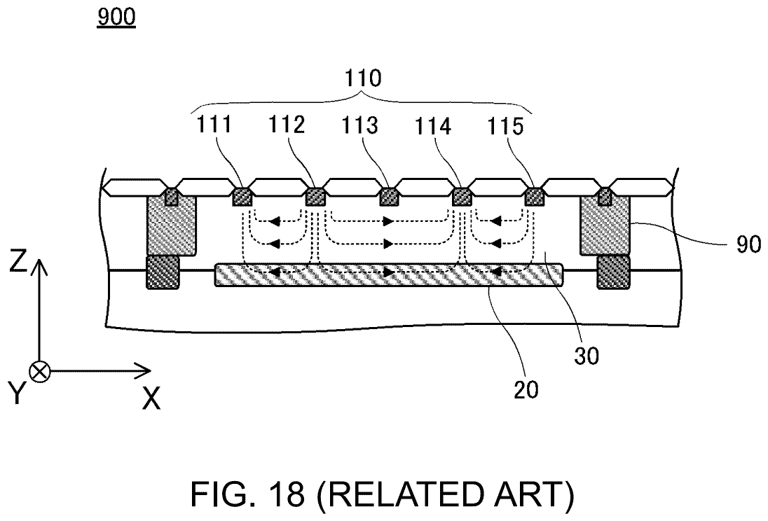

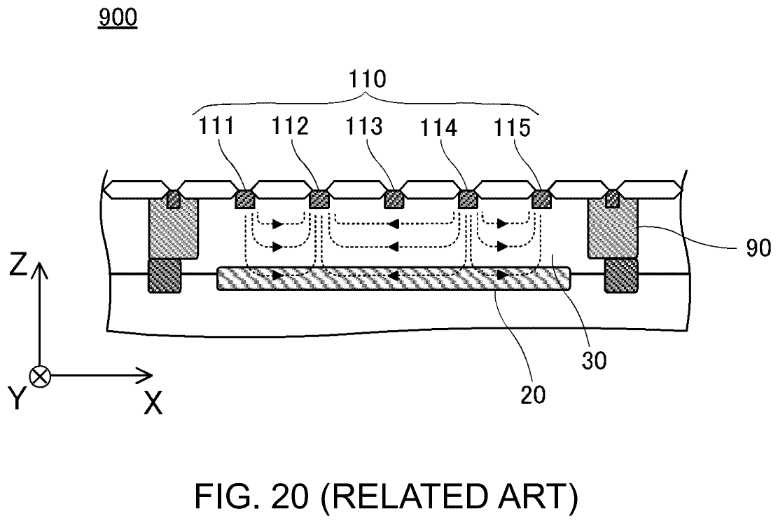

Further, in FIG. 14, FIG. 16, FIG. 18, and FIG. 20, a depletion layer is formed in the N-type epitaxial layer 30 on an inner peripheral side of the P-type element isolation diffusion layer 90, but illustration of this depletion layer is omitted.

Furthermore, since the electrode 930 is grounded by a wiring (not illustrated), the potential of the P-type element isolation diffusion layer 90 is 0 V.

### <Phase 1>

In Phase 1, as illustrated in FIG. 13A, FIG. 13B, and FIG. 14, taking the electrodes 111, 113, and 115 as current supply electrodes, a current is flowed from the electrode 113 respectively to the electrodes 111 and 115. Thus, a voltage of Vh is applied to the electrode 113, the electrodes 111 and 115 are set to 0 V, and a voltage of (½)×Vh is applied to the electrodes 112 and 114. Then, taking the electrodes 112 and 114 as voltage output electrodes, a voltage between the electrode 112 and the electrode 114 is obtained as a voltage Vout1.

At this time, since the voltages applied to the electrodes 111 to 115 are different from each other, the electric fields with respect to the P-type element isolation diffusion layer 90, which has a potential of 0 V, are different, and the width of the depletion layer DL generated in the N-type epitaxial layer 30 is not constant.

### <Phase 2>

In Phase 2, as illustrated in FIG. 15A, FIG. 15B, and FIG. 16, with the direction of flowing a current reversed compared to FIG. 13A and FIG. 14, a current is flowed respectively from the electrodes 111 and 115 to the electrode 113. Thus, a voltage of Vh is applied to the electrodes 111 and 115, the electrode 113 is set to 0 V, and a voltage of (½)×Vh is applied to the electrodes 112 and 114. Then, taking the electrodes 112 and 114 as voltage output electrodes, a voltage between the electrode 112 and the electrode 114 is obtained as an output voltage Vout2.

At this time, since the voltages applied to electrodes 111 to 115 are different from each other, the electric fields with respect to the P-type element isolation diffusion layer 90, which has a potential of 0 V, are different, and the width of the depletion layer DL generated in the N-type epitaxial layer 30 is not constant and is also different from the width of the depletion layer DL in Phase 1.

### <Phase 3>

In Phase 3, as illustrated in FIG. 17A, FIG. 17B, and FIG. 18, the current supply electrodes and the voltage output electrodes are replaced compared to FIG. 13A to FIG. 16, a current is flowed from the electrode 112 respectively to the electrodes 111 and 114, and a current is flowed from the electrode 115 to the electrode 114. Thus, a voltage of Vh is applied to the electrode 112, the electrode 114 is set to 0 V, and a voltage of (½)×Vh is applied to the electrodes 111, 113, and 115. Then, taking the electrodes 111, 113, and 115 as voltage output electrodes, a voltage between the electrode 113 and the electrodes 111 and 115 is obtained as an output voltage Vout3.

At this time, since the voltages applied to the electrodes 111 to 115 are different from each other, the electric fields with respect to the P-type element isolation diffusion layer 90, which has a potential of 0 V, are different, and the width of the depletion layer DL generated in the N-type epitaxial layer 30 is not constant and is also different from the width of the depletion layer DL in Phase 1 or 2.

### <Phase 4>

In Phase 4, as illustrated in FIG. 19A, FIG. 19B, and FIG. 20, with the direction of flowing a current reversed compared to FIG. 17A and FIG. 18, a current is flowed from the electrode 114 respectively to the electrodes 112 and 115, and a current is flowed from the electrode 111 to the electrode 112. Thus, a voltage of Vh is applied to the electrode 114, the electrode 112 is set to 0 V, and a voltage of (½)×Vh is applied to the electrodes 111, 113, and 115. Then, taking the electrodes 111, 113, and 115 as voltage output electrodes, a voltage between the electrode 113 and the electrodes 111 and 115 is obtained as an output voltage Vout4.

At this time, since the voltages applied to the electrodes 111 to 115 are different from each other, the electric fields with respect to the P-type element isolation diffusion layer 90, which has a potential of 0 V, are different, and the width of the depletion layer DL generated in the N-type epitaxial layer 30 is not constant and is also different from the width of the depletion layer DL in any of Phases 1 to 3.

In this manner, in the conventional vertical Hall element 900, upon changing a flow of current in each phase, the width of the depletion layer DL on the surface of the N-type epitaxial layer 30, which serves as the current path, does not remain constant. Thus, in the spinning current method, a distribution of the depletion layer width on the surface of the N-type epitaxial layer 30, which serves as the current path, differs and the resistance values between the electrodes change, which results in a decrease in removal accuracy.

As described above, the vertical Hall element according to an embodiment of the present invention includes an impurity diffusion layer of a second conductivity type formed on a surface of a semiconductor substrate of a first conductivity type, and a first electrode group disposed on a surface of the impurity diffusion layer and formed of three or more electrodes. The vertical Hall element further includes a high-resistance diffusion layer of the first conductivity type which is disposed in a ring shape on an outer periphery separated from the first electrode group and includes a second electrode group capable of being applied with a voltage such that an electric field with respect to the first electrode group becomes constant.

Accordingly, by separately disposing electrodes capable of being applied with voltages such that the distribution of the depletion layer width becomes constant in each phase, the vertical Hall element can remove an offset voltage with high accuracy in removing the offset voltage according to the spinning current method.

Although the embodiments of the present invention have been described above, the present invention is not limited to the embodiments and various modifications are possible within a scope without departing from the spirit of the present invention.

For example, although the first conductivity type has been described as the P-type and the second conductivity type has been described as the N-type, the conductivity types may be reversed, with the first conductivity type being the N-type and the second conductivity type being the P-type.

Further, in the above embodiments, the number of electrodes in the first electrode group has been set to five, but the present invention is not limited thereto. For example, in cases where the offset voltage can be reduced or can be tolerated to an extent that removal of the offset voltage according to the spinning current method is not required, it would be sufficient to provide at least two drive current supply electrodes and one Hall voltage output electrode, i.e., three electrodes in total. In other words, by adopting a configuration in which the electrodes 114 and 115 of the vertical Hall element 100 illustrated in FIG. 1 and other figures are not formed, since a layout area can be reduced, miniaturization of the vertical Hall element becomes possible.

What is claimed is:

1. A vertical Hall element formed on a surface of a semiconductor substrate of a first conductivity type, the vertical Hall element comprising:
an impurity diffusion layer of a second conductivity type formed on the surface of the semiconductor substrate;
a first electrode group disposed on a surface of the impurity diffusion layer and formed of three or more electrodes; and
a high-resistance diffusion layer of the first conductivity type which is disposed in a ring shape on an outer periphery separated from the first electrode group and comprises a second electrode group capable of being applied with a voltage such that an electric field with respect to the first electrode group becomes constant.

2. The vertical Hall element according to claim 1, wherein an inner peripheral part of the high-resistance diffusion layer is located at a constant distance from an outer peripheral part of the first electrode group.

3. The vertical Hall element according to claim 1, wherein an impurity concentration of the impurity diffusion layer increases as a depth increases.

4. The vertical Hall element according to claim 1, further comprising an element isolation region which is disposed on an outer periphery separated from the high-resistance diffusion layer and electrically isolates the vertical Hall element.

5. The vertical Hall element according to claim 4, wherein the first electrode group is disposed on a straight line.

6. The vertical Hall element according to claim 5, wherein the first electrode group comprises five electrodes,
a drive current is flowed from the electrode located at a center toward the electrodes located at both ends, and
a Hall voltage is detected between the two electrodes located between the electrode located at the center and the electrodes located at the both ends.
